(19) United States
(12) Patent Application Publication
(10) Pub. No.: US 2026/0096453 A1
(43) Pub. Date: Apr. 2, 2026

(54) SUBSTRATE PACKAGE HAVING MOISTURE DISSIPATION CHANNELS

(71) Applicant: TEXAS INSTRUMENTS INCORPORATED, DALLAS, TX (US)

(72) Inventors: CHUN PING LO, ALLEN, TX (US); RAJEN MANICON MURUGAN, DALLAS, TX (US); GUANGXU LI, ALLEN, TX (US); SYLVESTER ANKAMAH-KUSI, McKINNEY, TX (US); BLAKE TRAVIS, RICHARDSON, TX (US)

(21) Appl. No.: 18/899,633

(22) Filed: Sep. 27, 2024

(51) Int. Cl. H01L 23/498; H01L 21/48; H01L 23/00; H01L 23/31

(52) U.S. Cl. CPC H10W 70/635; H10W 42/00; H10W 70/095; H10W 70/65; H10W 74/111; H10W 90/724

(57) ABSTRACT

An electronic device includes a substrate, a first metal layer embedded in a first surface of the substrate and a second metal layer embedded in a second surface of the substrate opposite that of the first surface. A via layer is disposed between the first metal layer and the second metal layer and electrically connects the first metal layer and the second metal layer. The via layer includes a moisture dissipation feature. A die is attached to the first metal layer and a mold compound is formed over the die.

### TECHNICAL FIELD

The present disclosure relates to electronic devices, and more specifically to electronic device having at least one via layer comprising channels for moisture dissipation.

### BACKGROUND

Via layers comprising solid metal layer, bar layers, mesh layer, etc. can improve thermal performance of an integrated circuit (IC) substrate based package having one or more embedded trace layers in a substrate. The continuous metal configuration of these layer types, however, can trap moisture in the package during fabrication and/or during testing. The trapped moisture can cause delamination at an interface between non-metal material (e.g., mold compound) and metal layers or traces in the substrate of the package. In addition, the moisture and/or the delamination can cause cracking at a solder joint between an interconnect connected to a die and the metal layer. Cracked solder joints create electrical performance issues and/or electrical failure.

### SUMMARY

In a described example, an electronic device includes a substrate, a first metal layer embedded in a first surface of the substrate and a second metal layer embedded in a second surface of the substrate opposite that of the first surface. A via layer is disposed between the first metal layer and the second metal layer and electrically connects the first metal layer and the second metal layer. The via layer includes a moisture dissipation feature. A die is attached to the first metal layer and a mold compound is formed over the die.

In another described example, an electronic device includes a substrate having at least one recess defined in a first surface and at least one recess defined in a second surface that is opposite that of the first surface. A first metal layer is deposited in the at least one recess in the first surface of the substrate and a second metal layer is deposited in the at least one recess in the second surface of the substrate. A via layer electrically connects the first metal layer and the second metal layer, the via layer comprising a first via set, a second via set, and a moisture dissipation feature. A die is attached to the first metal layer and a mold compound formed over the die.

In still another described example, a method includes forming a via layer in a substrate, where the via layer includes vias, via bars connecting a portion of adjacent vias, and a moisture dissipation feature. A first metal layer is formed in a surface of a substrate and a second metal layer is formed in an opposite surface of the substrate such that the first metal layer is electrically connected to the second metal layer via the via layer. Interconnects are disposed on the first metal layer and a die is placed on a surface of the interconnects. A mold compound is formed over the die and the interconnects.

### BRIEF DESCRIPTION OF THE DRAWINGS

FIG. 1 is a cross-sectional view of an example electronic device.

FIG. 2 is a top view of an example first metal layer of the example electronic device of FIG. 1.

FIG. 3 is a top view of an example second metal layer of the example electronic device of FIG. 1.

FIG. 4A is a top view of an example via layer of the example electronic device of FIG. 1.

FIG. 4B is a close-up top view of example via cells of the example via layer of FIG. 4A.

FIG. 5 is a top view of another example via layer.

FIG. 6 is a block diagram flow chart explaining a fabrication process of the electronic device of FIG. 1.

FIG. 7A illustrates a cross-sectional view of a substrate in the early stages of fabrication.

FIG. 7B illustrates a cross-sectional view of the substrate of FIG. 7A after undergoing a first laser drilling/etching process to form of vias and a first recess.

FIG. 7C illustrates a cross-sectional view of the substrate of FIG. 7B after undergoing a first photoresist material layer patterning.

FIG. 7D illustrates a cross-sectional view of the substrate of FIG. 7C after undergoing a first plating process.

FIG. 7E illustrates a cross-sectional view of the substrate of FIG. 7D after undergoing removal of the first photoresist material layer.

FIG. 7F illustrates a cross-sectional view of the substrate of FIG. 7E after rotation of the substrate by 180°.

FIG. 7G illustrates a cross-sectional view of the substrate of FIG. 7F after undergoing a second laser drilling/etching process to form second recesses.

FIG. 7H illustrates a cross-sectional view of the substrate of FIG. 7G after undergoing a second photoresist material layer patterning.

FIG. 7I illustrates a cross-sectional view of the substrate of FIG. 7H after undergoing a second plating process.

FIG. 7J illustrates a cross-sectional view of the substrate of FIG. 7I after undergoing removal of the second photoresist material layer.

FIG. 7K illustrates a cross-sectional view of the substrate of FIG. 7J after rotation of the substrate by 180°.

FIG. 7L illustrates a cross-sectional view of the substrate of FIG. 7K after undergoing deposition of interconnects on the first metal layer.

FIG. 7M illustrates a cross-sectional view of the substrate of FIG. 7L after placement of a die on the interconnects.

FIG. 7N illustrates a cross-sectional view of the substrate of FIG. 7M after undergoing a formation of a mold compound to form the electronic device of FIG. 1.

### DETAILED DESCRIPTION

Substrate based integrated circuit (IC) packages include metal layers or traces embedded in the substrate with via layers between adjacent metal layers. The via layers may be comprised of a solid metal layer, a bar layer, mesh structure, etc. Since the via layers contain continuous amounts of metal, the via layers can improve the thermal performance of the IC package. The continuous metal configuration of these layer types, however, can trap moisture in the package during fabrication and/or during testing. More specifically, moisture can become trapped during preconditioning testing (e.g., moisture soak process). During subsequent testing (e.g., infrared reflow), the trapped moisture can cause delamination at an interface between non-metal material (e.g., mold compound) and metal layers or traces in the substrate of the package. The delamination becomes exacerbated during temperature cycling testing, which can lead to cracking at a solder joint between an interconnect connected to a die and the metal layer. The cracked solder joints create electrical performance issues and/or electrical failure.

Disclosed herein is an electronic device and process to mitigate the amount of moisture that gets trapped in a substrate based IC package during fabrication and/or testing of the electronic device that overcomes the aforementioned disadvantages. The mitigation of moisture trapped in the electronic device reduces or eliminates delamination between the non-metal material (e.g., mold compound) and the metal material (e.g., metal layer or trace). This in turn reduces the probability of solder cracks occurring between the interconnect connected to the die and the metal layer.

The electronic device may include one or more metal or trace layers embedded in a substrate with a via layer disposed between adjacent metal layers. The via layers are comprised of multiple via cells where each via cell is comprised of a plurality of vias filled with a conductive metal (e.g., copper). Adjacent vias in the via cell may or may not be connected with conductive bars. In addition, adjacent vias in adjacent vias cells may or may not be connected with the conductive bars. Thus, openings can be formed between adjacent vias and between several adjacent via cells in the absence of the conductive bars. Therefore, channels ranging in any length can be formed along the via layer between multiple adjacent vias and multiple adjacent via cells. The channels facilitate the dissipation of moisture during fabrication and/or testing of the electronic device. More specifically, the channels create paths for the moisture to dissipate or desorb during fabrication (e.g., during solder reflow) and/or testing.

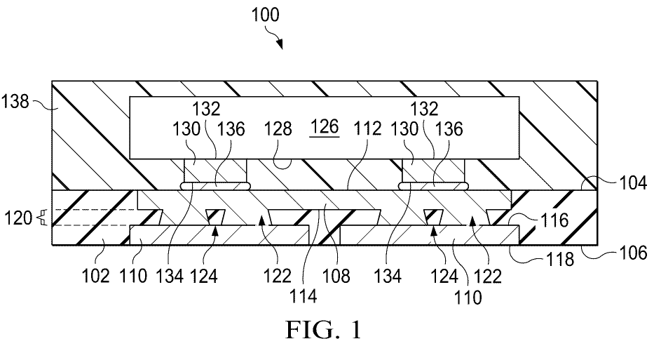

FIG. 1 is a cross-sectional view of an example electronic device (e.g., integrated circuit (IC)) 100. The electronic device 100 is a substrate type device and can be comprised of any type of a multi-layer substrate integrated circuit (IC) including, but not limited to a land-grid array (LGA), a ball-grid array (BGA) package, etc. Thus, the example electronic device 100 illustrated in FIG. 1 is for illustrative purposes only and is not intended to limit the scope of the invention.

The electronic device 100 includes multiple metal layers (traces) embedded in a substrate (e.g., dielectric) 102 where the substrate 102 has a first surface 104 and a second surface 106. The number of metal layers embedded in the substrate 102 can be any number ranging from 2 to N, where N is the maximum number for a given electronic device 100. For simplicity, the example electronic device 100 described herein and illustrated in FIG. 1 includes two metal layers comprising a first metal layer 108 and a second metal layer 110. The first metal layer 108 has a first surface 112 and a second surface 114. The first surface 112 is flush with the first surface 104 of the substrate 102. The second metal layer 110 has a first surface 116 and a second surface 118. The second surface 118 is flush with the second surface 106 of the substrate 102.

A via layer 120 is disposed between the first metal layer 108 and the second metal layer 110. In other example electronic device packages, however, another via layer 120 may be disposed between the second metal layer 110 and a third metal layer, and still another via layer 120 may be disposed between the third metal layer and a fourth metal layer, etc. The via layer 120 provides an electrical connection between the first metal layer 108 and the second metal layer 110. As will be described in detail below, the via layer 120 includes via cells comprised of vias 122 and channels (moisture dissipation/reduction feature or delamination mitigation feature) 124 defined between the vias 122. As described above, the vias 122 are comprised of solid metal (e.g., copper) to facilitate the electrical connection between the first metal layer 108 and the second metal layer 110. In addition, the solid vias 122 also assist in the thermal performance of the electronic device 100. The channels 124 allow moisture to dissipate or desorb during fabrication and/or testing of the electronic device 100 thereby mitigating delamination.

The electronic device 100 further includes a die 126 having an active side 128. The active side of the die 126 is connected to the first surface 112 of the first metal layer 108 via conductive metal interconnects (e.g., copper pillars) 130. Specifically, a first surface 132 of the interconnects 130 are connected to the active side 128 of the die 126 and a second surface 134 of the interconnects 130 are connected to the first surface 112 of the first metal layer 108 via a solder layer 136. The solder layer is approximately 5-20 microns thick. A mold compound 138 encapsulates the die 126, the interconnects 130, and the solder layer 136.

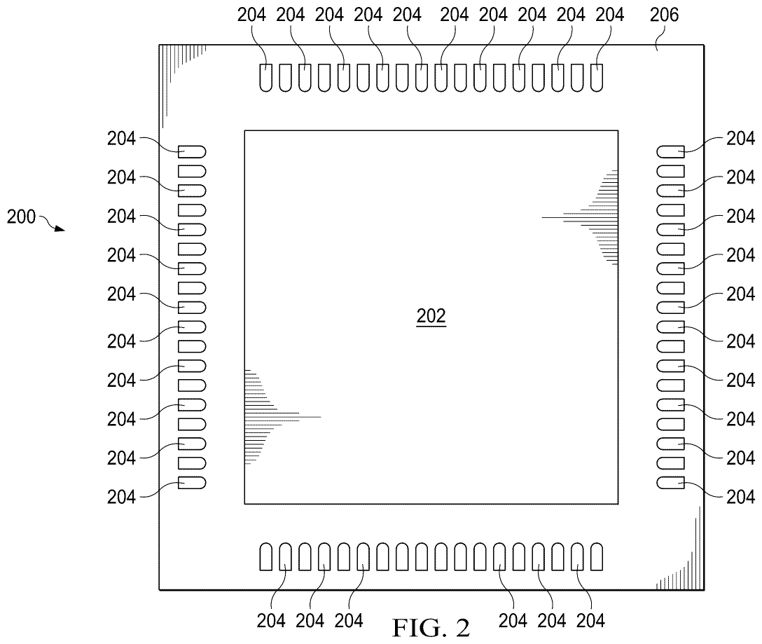

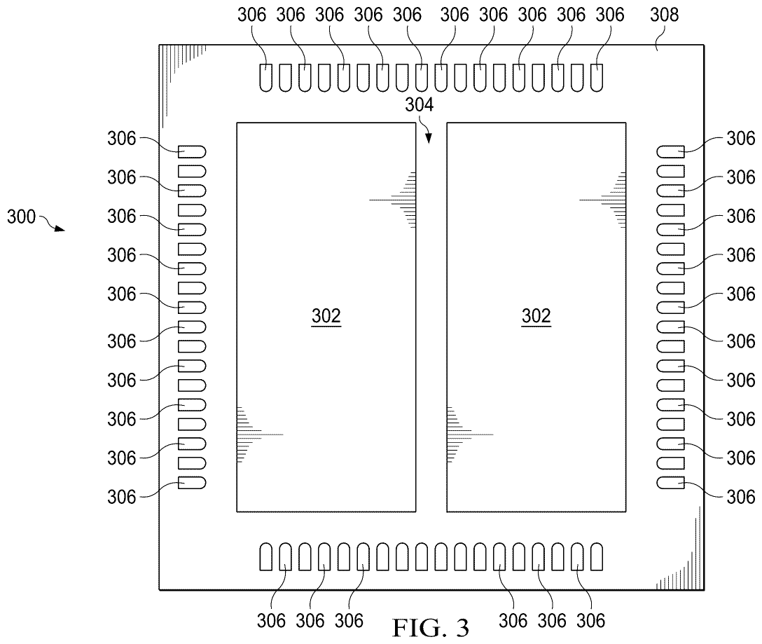

FIGS. 2 and 3 are example top view illustrations of an example first metal layer 200 and an example second metal layer 300. The example first metal layer 200 and the example second metal layer 300 illustrated in FIGS. 2 and 3 are similar to the first metal layer 108 and the second metal layer 110 illustrated in FIG. 1. Thus, reference is to be made to the example of FIG. 1 in the following description of the examples in FIGS. 2 and 3.

The first metal layer 200 is comprised of a first plated metal portion 202 that electrically and mechanically connects to a die via interconnects and solder joints, as described above. The configuration of the first plated metal portion 202 can be comprised a single solid metal portion or can be comprised of multiple metal portions physically separated by a gap or gaps. For simplicity, the configuration of the first plated metal portion 202 is a single metal portion. Thus, the example first metal layer 200 illustrated in FIG. 2 is for illustrative purposes only and is not intended to limit the scope of the invention. The first metal layer 200 further includes pins or leads 204 disposed around its perimeter 206.

The second metal layer 300 is comprised of a pair of second plated metal portions 302 that electrically and mechanically connect to the first plated metal portion 202 via a via layer as described above and as described in further detail below. The configuration of the second plated metal portions 302 can be comprised a single solid metal portion or can be comprised of multiple metal portions physically separated by a gap or gaps. For simplicity, the configuration of the second plated metal portions 302 are comprised a pair of plated metal portions physically separated by a gap 304. Thus, the example second metal layer 300 illustrated in FIG. 3 is for illustrative purposes only and is not intended to limit the scope of the invention. The second metal layer further includes pins or leads 306 disposed around its perimeter 308.

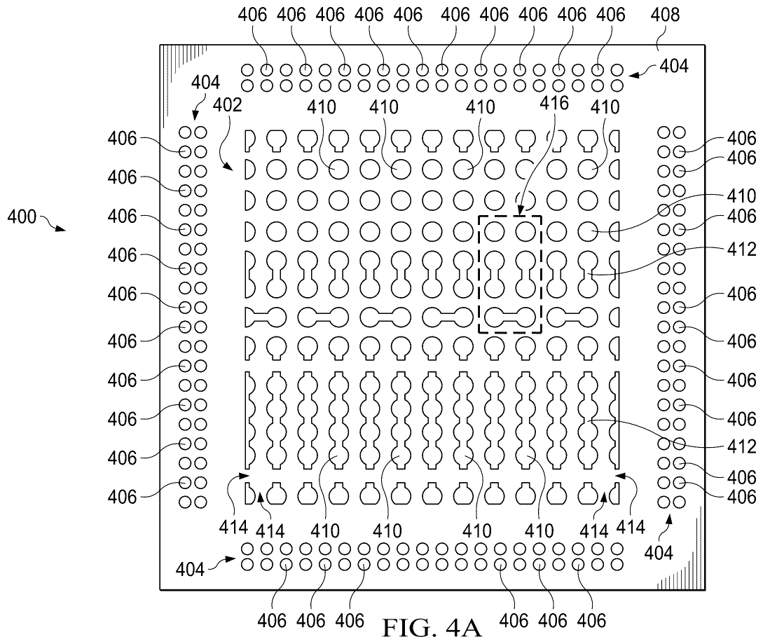

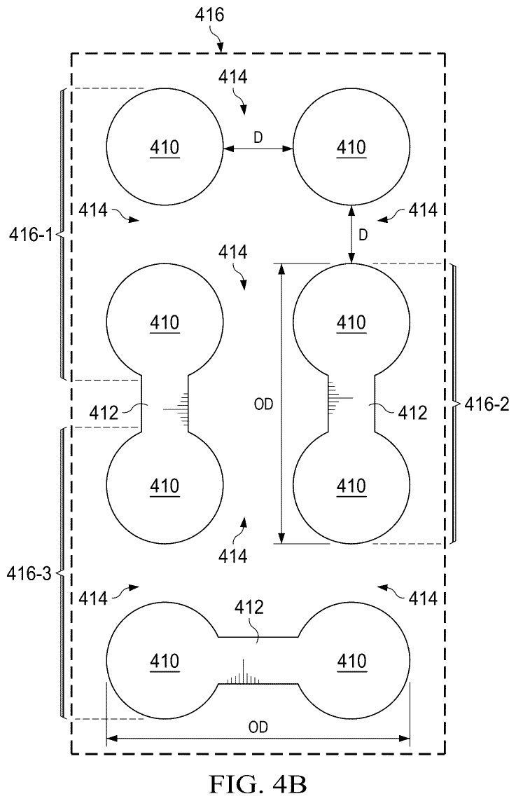

FIG. 4A is a top view illustration of an example via layer (via channel layer) 400 illustrated in FIG. 1. The via layer 400 provides an electrical connection between the first metal layer 108, 200 and the second metal layer 110, 300 described above. The configuration of the via layer 400 also facilitates the thermal performance of the electronic device 100. The example via layer 400 illustrated in FIG. 4 is similar to the via layer 120 illustrated in FIG. 1. Thus, reference is to be made to the example of FIG. 1 in the following description of the example via layer 400 in FIG. 4.

The via layer 400 is comprised vias that are each filled with a conductive metal (e.g., copper) to facilitate electrical conductivity between the first metal layer 108, 200 and the second metal layer 110, 300. Specifically, the via layer 400 includes a first via set (inner via set) 402 and a second via set (outer via set) 404. The first via set 402 electrically connects the first plated metal portion 202 of the first metal layer 108, 200 and the pair of second plated metal portions 302 of the second metal layer 110, 300. The second via set 404 is comprised of second vias 406 filled with an electrically conductive metal (e.g., copper) and are provided around all or a portion of a perimeter 408 of the via layer 400. The second via set 404 provides an electrical connection between the pins or leads 204 of the first metal layer 108, 200 and the pins or leads 306 of the second metal layer 110, 300.

Still referring to FIG. 4A and also to FIG. 4B, the first via set 402 is comprised of first vias 410, via bars 412, and channels (moisture dissipation/reduction feature or delamination mitigation feature) 414. Both the first vias 410 and the via bars 412 are filled with an electrically conductive metal (e.g., copper). The via bars 412 extend between and connect a portion but not all adjacent vias 410. As illustrated in FIG. 4B, the channels 414 are defined between at least a portion of adjacent first vias 410 where via bars 412 are absent. As mentioned above, the channels 414 facilitate dissipation or desorption of moisture during fabrication and/or testing. In some applications, the via bars 412 may connect several adjacent first vias 410. Based on the type and application of the electronic device 100, the number of via bars 412 and thus, the number of channels 414 may vary.

Multiple adjacent first vias 410 can form a via cell 416. The via cell 416 can be arranged in a pattern (e.g., square, rectangular, circular, triangular, etc.). In the example via layer 400 illustrated in FIG. 4A, the via cell 416 is arranged in a square pattern as indicated by the dashed box in FIG. 4A. Thus, in the disclosed example via layer 400, four vias 410 comprise the via cell 416. The example via cell 416, however, can be comprised of less than four vias 410 or more than four vias 410 based on the pattern of the via cell 416. Thus, the example via cell 416 illustrated in FIG. 4A is for illustration purposes only and is not intended to limit the scope of the invention.

FIG. 4B is an illustration of three example vias cells 416, a first via cell 416-1, a second via cell 416-2, and a third via cell 416-3 (collectively “416”). The via cells 416 can overlap thus a pair of vias 410 from one via cell 416 can be part of an adjacent via cell 416. For example, two vias 410 from the second via cell 416-2 are part of the first via cell 416-1 and the two other vias 410 of the second via cell 416-2 are part of the third via cell 416-3. Each via cell 416 can have an outer dimension OD of approximately 70-100 um. In addition, a distance D between adjacent vias 410 is approximately 20-50 um. Each via cell 416 may or may not include via bars 412 as illustrated in FIG. 4B.

Still further, each via cell can have different combination of via bars 412 and channels 414. For example, the first via cell 416-1 has no via bars 412 and four channels 414. The second via cell 416-2 has two via bars 412 and two channels 414. Finally, the third via cell 416-3 has one via bar 412 and three channels 414. Thus, based on the type and application of the electronic device 100, the combination of via bars 412 and channels 414 can vary. In addition, the via bars 412 may be arranged either parallel or perpendicular to each other within the same cell or in adjacent cells. For example, the two via bars 412 in the second via cell 416-2 are parallel with respect to each other. The via bar 412 in the third via cell 416-3, however, is perpendicular to the two vias bars 412 in the second via cell 416-2. Thus, from a top view perspective, the vias bars 412 may be arranged horizontally or vertically.

As mentioned above, the addition of the channels 414 facilitate the dissipation and desorption of moisture during fabrication and testing of the electronic device. More specifically, after fabrication the electronic device undergoes a preconditioning test (e.g., moisture soak). During the preconditioning test, the electronic package absorbs moisture during the soaking process. After the moisture soak, the electronic device undergoes an infrared (IR) reflow where the electronic device is subjected to temperatures of approximately 250° C. During the IR reflow, the moisture naturally dissipates or desorbs from the package. Some of the moisture, however, can become trapped inside the package and cannot dissipate quickly. As a result, larger vapor pressure builds up in the package, which causes delamination at the interface of the mold compound and metal layers. The channels 414 create paths for the moisture to quickly dissipate during the IR reflow, thereby reducing the possibility of vapor pressure building up in the package ultimately mitigating delamination and solder cracking.

Furthermore, the channels 414 do not significantly impact thermal performance of the electronic device 100 as compared to solid metal via layers or via bar/mesh layers. As illustrated in Table 1 below, the solid metal via layer increases 1.99° C. for each additional increase in watts and the via bar/mesh layer increases 2.18° C. for each additional increase in watts. The via layer with moisture channels 414 only increases by 2.27° C. for each additional increase in watts. Thus, the amount of increase from the solid metal via layer to the via layer with the moisture channels 414 is an increase of only 0.28° C. for each additional increase in watts.

TABLE 1

| Vial Layer Configuration | Thermal Performance |
|---|---|
| Solid Metal Via Layer | 1.99° C./W |
| Via Bar/Mesh Layer | 2.18° C./W |
| Vial Layer with Moisture Channels | 2.27° C./W |

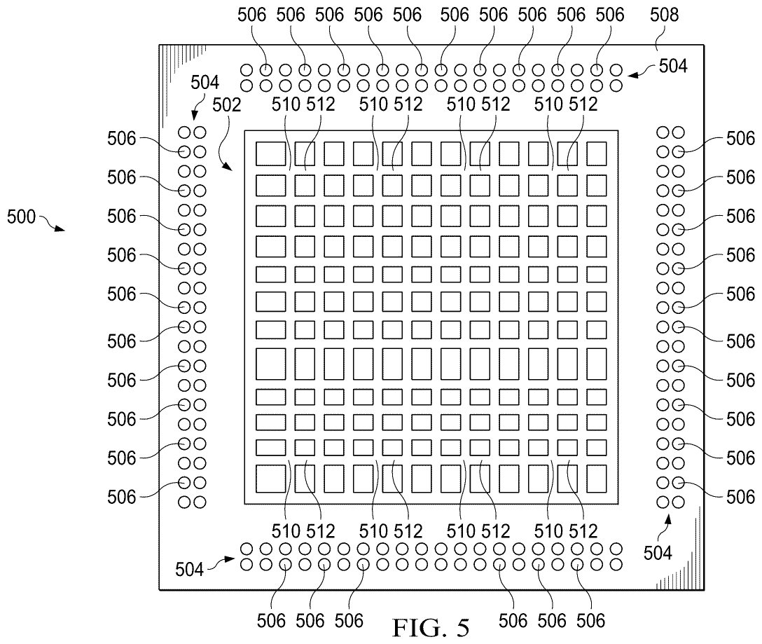

FIG. 5 is a top view illustration of another example via layer 500. The example via layer 500 is a via bar or mesh layer that includes a first via set 502 and a second via set 504. The second via set 504 is comprised of vias 506 filled with an electrically conductive metal (e.g., copper) and are provided around all or a portion of a perimeter 508 of the via layer 500. The second via set 504 provides an electrical connection between the pins or leads between metal layers in a substrate based IC package. The first via set 502 is comprised of vias 510 and via bars 512 that connect all the vias 510 to adjacent vias 510. Thus, there are no channels defined between adjacent vias 510. As illustrated in Table 1 above, although, the via bar/mesh layer 500 has a slightly better thermal performance than the via channel layer 400 described above, the via bars 512 in the via bar layer 500 increase the possibility of moisture becoming trapped inside the electronic device during fabrication and/or testing, which leads to delamination. Thus, the significant reduction in the possibility of moisture becoming trapped inside the electronic device far outweighs the slight decrease in thermal performance between the via channel layer 400 and the via bar layer 500.

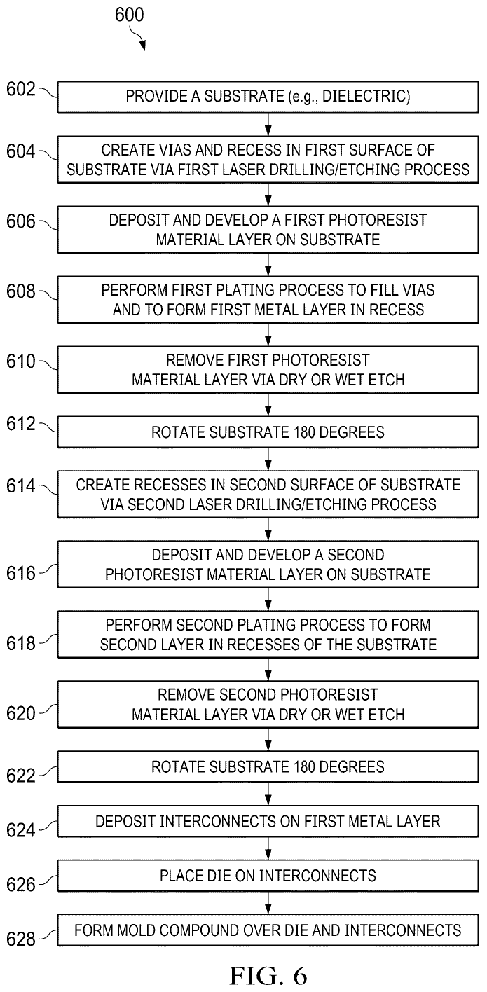

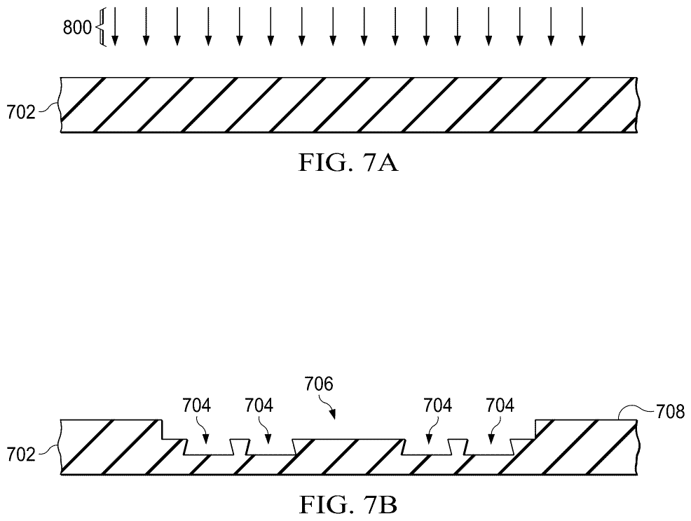

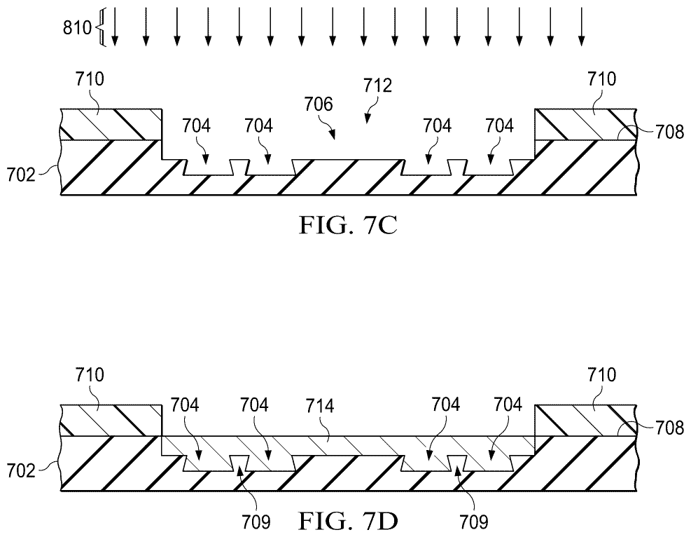

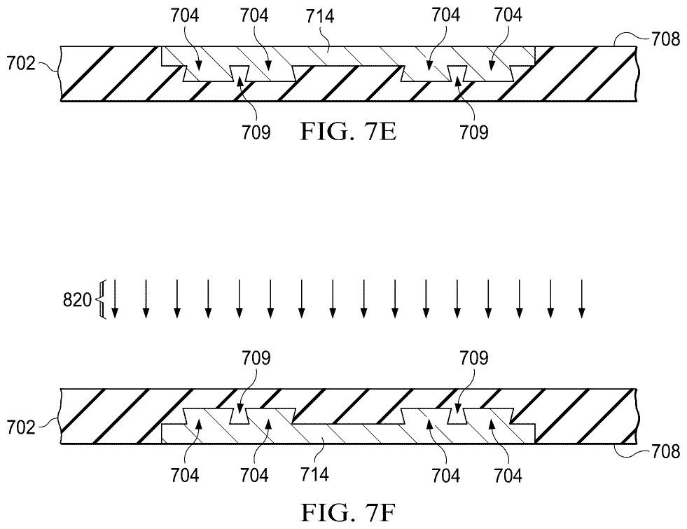

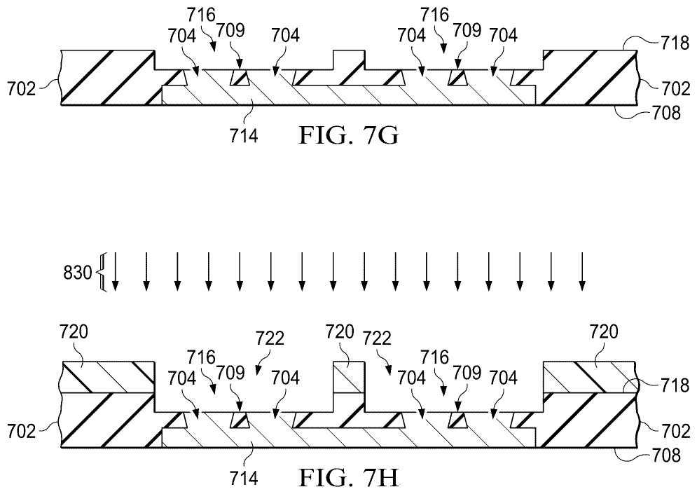

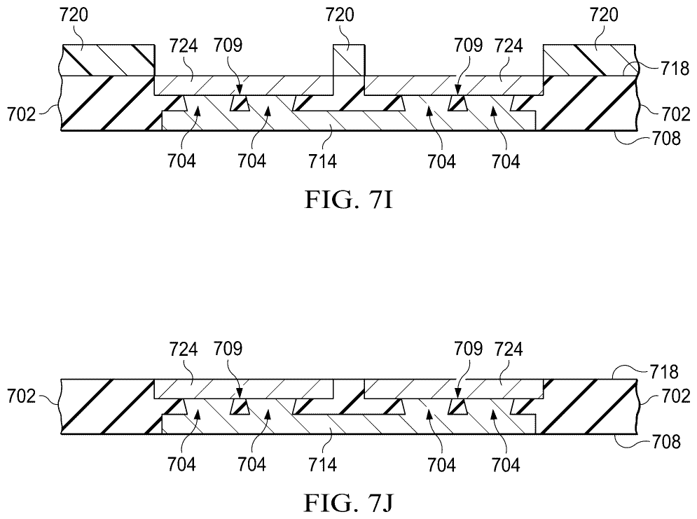

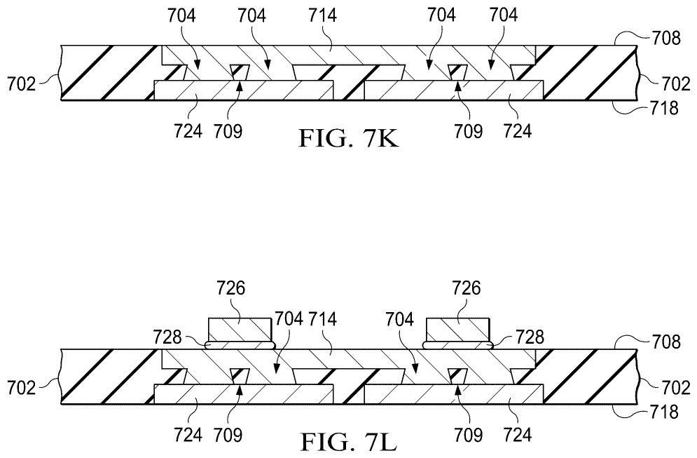

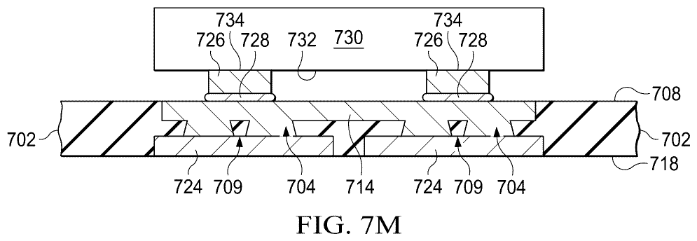

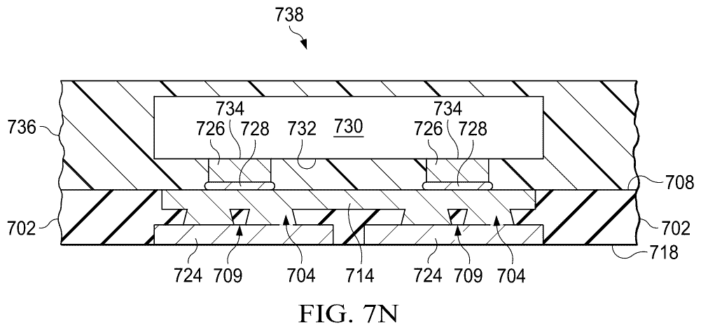

FIG. 6 is a block diagram flow chart explaining a fabrication process 600 and FIGS. 7A-7N illustrate a fabrication process associated with the formation of the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 6 and 7A-7N is an example method illustrating the example configuration of FIG. 1, other methods and configurations are possible. It is understood that although the method illustrated in FIGS. 6 and 7A-7N depicts the fabrication process of a single electronic device, the process applies to an array of electronic devices. Thus, after fabrication of the array of electronic devices the array is singulated to separate each electronic device 100 from the array.

Referring to FIG. 6 and to FIGS. 7A-7N, the fabrication process 600 of the electronic device 100 illustrated in FIG. 1 begins at 602 with a substrate (e.g., dielectric) 702. At 604, the configuration in FIG. 7A undergoes a first laser drilling/etching process 800 to drill vias 704 and to etch a first recess 706 in a first surface 708 of the substrate 702 resulting in the configuration of FIG. 7B. Channels (moisture dissipation/reduction feature or delamination mitigation feature) 709 are defined between adjacent vias to facilitate the dissipation of moisture during fabrication and/or testing of the electronic device. At 606, a first photoresist material layer 710 overlies the substrate 702 and is patterned and developed to expose openings 712 in the first photoresist material layer 710 over the substrate 702, resulting in the configuration of FIG. 7C. The first photoresist material layer 710 can have a thickness that varies in correspondence with the wavelength of radiation used to pattern the first photoresist material layer 710. The first photoresist material layer 710 may be formed over the substrate 702 via spin-coating or spin casting deposition techniques, selectively irradiated (e.g., via deep ultraviolet (DUV) irradiation) and developed to form the openings 712.

At 608, the configuration in FIG. 7C undergoes a first plating (electroplating) process 810 to fill the vias 704 with a conductive material (e.g., copper) and to plate a first metal layer (trace) (e.g., copper) 714 in the recess 706 of the substrate 702 resulting in the configuration of FIG. 7D. The configuration of the first metal layer 714 can be comprised a single solid metal portion or can be comprised of multiple metal portions physically separated by a gap or gaps. For simplicity, the configuration of the first metal layer 714 is a single metal portion. Thus, the number of recesses etched in the first surface 708 of the substrate 702 can be a single recess or more than one recess separated by a gap or gaps to accommodate more than one metal portions that comprise the first metal layer 714. Therefore, the example first metal layer 714 illustrated in FIG. 7D is for illustrative purposes only and is not intended to limit the scope of the invention.

At 610, the first photoresist material layer 710 is removed via a dry or wet etch process resulting in the configuration of FIG. 7E. At 612, the configuration in FIG. 7E is rotated 180° resulting in the configuration of FIG. 7F. At 614, the configuration of FIG. 7F undergoes a second laser drilling/etching process 820 to etch one or more second recesses 716 in a second surface 718 of the substrate 702 opposite that of the first surface 708 resulting in the configuration of FIG. 7G.

At 616, a second photoresist material layer 720 overlies the substrate 702 and is patterned and developed to expose openings 722 in the second photoresist material layer 720 over the substrate 702, resulting in the configuration of FIG. 7H. The second photoresist material layer 720 can have a thickness that varies in correspondence with the wavelength of radiation used to pattern the second photoresist material layer 720. The second photoresist material layer 720 may be formed over the substrate 702 via spin-coating or spin casting deposition techniques, selectively irradiated (e.g., via deep ultraviolet (DUV) irradiation) and developed to form the openings 722.

At 618, the configuration in FIG. 7H undergoes a second plating (electroplating) process 830 to plate a second metal layer (trace) (e.g., copper) 724 in the recesses 716 of the substrate 702 resulting in the configuration of FIG. 7I. The configuration of the second metal layer 724 can be comprised a single solid metal portion or can be comprised of multiple metal portions physically separated by a gap or gaps. For simplicity, the configuration of the second metal layer 724 is a pair of metal portions. Thus, the number of recesses etched in the second surface 718 of the substrate 702 can be a single recess or more than one recess separated by a gap or gaps to accommodate more than one metal portions that comprise the second metal layer 724. Therefore, the example second metal layer 724 illustrated in FIG. 7I is for illustrative purposes only and is not intended to limit the scope of the invention.

At 620, the second photoresist material layer 720 is removed via a dry or wet etch process resulting in the configuration of FIG. 7J. At 622, the configuration in FIG. 7J is again rotated 180° resulting in the configuration of FIG. 7K. At 624, interconnects 726 are deposited on the first metal layer 714 via a solder layer 728 resulting in the configuration of FIG. 7L. At 626, a die 730 is placed on the interconnects 726 such that an active side 732 of the die 730 is placed on a surface 734 of the interconnects 726 resulting in the configuration of FIG. 7M. At 628, a mold compound 736 is formed over the die 730 and the interconnects 726 such that the mold compound 736 contacts the substrate 702 resulting in the electronic device 738 illustrated in the configuration of FIG. 7N.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate;
a first metal layer embedded in a first surface of the substrate;
a second metal layer embedded in a second surface of the substrate opposite that of the first surface;
a via layer disposed between the first metal layer and the second metal layer, the via layer electrically connecting the first metal layer and the second metal layer, the via layer comprising a moisture dissipation feature;
a die attached to the first metal layer; and
a mold compound formed over the die.

2. The electronic device of claim 1, wherein the via layer includes vias filled with an electrically conductive metal, and the moisture dissipation feature comprises channels defined between the vias, the channels facilitating dissipation of moisture during fabrication and/or testing of the electronic device.

3. The electronic device of claim 1, wherein the via layer includes vias, via bars connecting at least a portion of adjacent vias, and the moisture dissipation feature comprises channels defined between adjacent vias in the absence of the via bars.

4. The electronic device of claim 1, wherein the via layer includes via cells comprising adjacent vias arranged in a pattern and the moisture dissipation feature comprises channels defined between the adjacent vias.

5. The electronic device of claim 1, wherein the via layer includes via cells comprising adjacent vias arranged in a pattern, at least one via bar connecting two of the adjacent vias, and the moisture dissipation feature comprising channels defined between remaining adjacent vias.

6. The electronic device of claim 1, wherein the via layer includes a first via set and a second via set, the first via set comprising first vias, via bars connecting at least a portion of adjacent first vias, and the moisture dissipation feature comprises channels defined between adjacent first vias in the absence of the via bars.

7. The electronic device of claim 6, wherein the second via set includes second vias provided around a perimeter of the via layer, the second vias electrically connecting pins on the first metal layer with pins of the second metal layer.

8. The electronic device of claim 1 further comprising interconnects connecting the die to the first metal layer.

9. The electronic device of claim 8, wherein an active side of the die is attached to a surface of the interconnects.

10. An electronic device comprising:
a substrate having at least one recess defined in a first surface and at least one recess defined in a second surface that is opposite that of the first surface;
a first metal layer deposited in the at least one recess in the first surface of the substrate;
a second metal layer deposited in the at least one recess in the second surface of the substrate;
a via layer electrically connecting the first metal layer and the second metal layer, the via layer comprising a first via set, a second via set, and a moisture dissipation feature;
a die attached to the first metal layer; and
a mold compound formed over the die.

11. The electronic device of claim 10, wherein the first via set includes first vias filled with an electrically conductive metal, and the moisture dissipation feature comprises channels defined between the first vias, the channels facilitating dissipation of moisture during fabrication and/or testing of the electronic device.

12. The electronic device of claim 11, wherein the second via set includes second vias provided around a perimeter of the via layer, the second vias electrically connecting pins on the first metal layer with pins of the second metal layer.

13. The electronic device of claim 10, wherein the first via set includes vias, via bars connecting at least a portion of adjacent vias, and the moisture dissipation feature comprises channels defined between adjacent vias in the absence of the via bars.

14. The electronic device of claim 10, wherein the first via set includes via cells comprising adjacent vias arranged in a pattern and the moisture dissipation feature comprises channels defined between the adjacent vias.

15. The electronic device of claim 10, wherein the first via set includes via cells comprising adjacent vias arranged in a pattern, at least one via bar connecting two of the adjacent vias, and the moisture dissipation feature comprising channels defined between remaining adjacent vias.

16. The electronic device of claim 10 further comprising interconnects connecting the die to the first metal layer, wherein an active side of the die is attached to a surface of the interconnects.

17. A method comprising:
forming a via layer in a substrate, the via layer including vias, via bars connecting a portion of adjacent vias, and a moisture dissipation feature;
forming a first metal layer in a surface of a substrate;
forming a second metal layer in an opposite surface of the substrate, the first metal layer electrically connected to the second metal layer via the via layer;
depositing interconnects on the first metal layer;
placing a die on a surface of the interconnects; and
forming a mold compound over the die and the interconnects.

18. The method of claim 17, wherein the moisture dissipation feature is comprised of channels formed between at least a portion of adjacent vias in the via layer, the channels being configured to dissipate moisture.

19. The method of claim 17, wherein forming a first metal layer in a surface of a substrate includes etching a first recess in the surface of the substrate and performing a first plating process to deposit metal in the first recess.

20. The method of claim 19, wherein forming a second metal layer in an opposite surface of the substrate includes etching at least one second recess in the opposite surface of the substrate and performing a second plating process to deposit metal in the at least one second recess.
